(19) United States
(12) Patent Application Publication
(10) Pub. No.: US 2024/0145406 A1
(43) Pub. Date: May 2, 2024

(54) SEMICONDUCTOR CIRCUIT AND SEMICONDUCTOR DEVICE

(71) Applicant: ROHM CO., LTD., Kyoto (JP)

(72) Inventor: Takatsugu WACHI, Kyoto (JP)

(21) Appl. No.: 18/477,870

(22) Filed: Sep. 29, 2023

(30) Foreign Application Priority Data
Nov. 2, 2022 (JP) 2022-176115

(51) Int. Cl. H01L 23/552; H01L 23/522; H01L 23/528

(52) U.S. Cl. CPC H01L 23/552; H01L 23/5222; H01L 23/5227; H01L 23/528; H01L 24/16; H01L 2224/16225

(57) ABSTRACT

A semiconductor circuit includes: an input capacitor; a first arm circuit including a first switching element and a second switching element; a second arm circuit including a third switching element and a fourth switching element; and a shield, wherein the shield overlaps with at least a part of the second arm circuit in a plan view, wherein a length of a second path of the second arm circuit is longer than a length of a first path of the first arm circuit, and wherein a length of a section of the shield that overlaps with the second arm circuit in a plan view and extends along the second path is longer than a length of a section of the shield that overlaps with the first arm circuit in a plan view and extends along the first path.

### CROSS-REFERENCE TO RELATED APPLICATION

This application is based upon and claims the benefit of priority from Japanese Patent Application No. 2022-176115, filed on Nov. 2, 2022, the entire contents of which are incorporated herein by reference.

### TECHNICAL FIELD

The present disclosure relates to a semiconductor circuit and a semiconductor device including the semiconductor circuit.

### BACKGROUND

An example of a power supply circuit for a step-down DC-DC converter is known. The power supply circuit includes two transistors. In the power supply circuit, one arm circuit is constituted by the two transistors. The arm circuit constitutes a half-bridge circuit. A power supply voltage input to the power supply circuit is stepped-down to a predetermined voltage by an inductor and an output capacitor, which are driven by the two transistors, respectively, and electrically connected to the half-bridge circuit.

Here, in the power supply circuit described above, when it is required to flow a larger current, it is necessary to configure a half-bridge circuit including a plurality of arm circuits. In this case, when lengths of conductive paths of the plurality of arm circuits differ from one another greatly, differences occur among magnitudes of magnetic fields generated from the plurality of arm circuits. As a result, an effect of canceling out the magnetic fields of the plurality of arm circuits due to mutual inductance is not sufficiently exhibited, and a degree of noise generated from the plurality of arm circuits becomes uneven. This may increase influence of the noise on the half-bridge circuit.

### BRIEF DESCRIPTION OF DRAWINGS

The accompanying drawings, which are incorporated in and constitute a part of the specification, illustrate embodiments of the present disclosure.

FIG. 1 is a configuration diagram of a semiconductor circuit according to a first embodiment of the present disclosure.

FIG. 2 is a plan view of a semiconductor device according to the first embodiment of the present disclosure, and shows a part of a sealing resin as being transparent.

FIG. 3 is a plan view of the semiconductor device shown in FIG. 2, and shows a shield, an input capacitor, and a semiconductor element as being transparent while omitting the sealing resin.

FIG. 4 is a bottom view of the semiconductor device shown in FIG. 2.

FIG. 5 is a cross-sectional view taken along line V-V in FIG. 3.

FIG. 6 is a cross-sectional view taken along line VI-VI in FIG. 3.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a cross-sectional view taken along line X-X in FIG. 3.

FIG. 11 is a configuration diagram of a semiconductor circuit according to a second embodiment of the present disclosure.

FIG. 12 is a plan view of a semiconductor device according to the second embodiment of the present disclosure.

FIG. 13 is a bottom view of the semiconductor device shown in FIG. 12.

FIG. 14 is a cross-sectional view taken along line XIV-XIV in FIG. 12.

FIG. 15 is a cross-sectional view taken along line XV-XV in FIG. 12.

FIG. 16 is a cross-sectional view taken along line XVI-XVI in FIG. 12.

FIG. 17 is a cross-sectional view taken along line XVII-XVII in FIG. 12.

FIG. 18 is a cross-sectional view taken along line XVIII-XVIII in FIG. 12.

FIG. 19 is a configuration diagram of a semiconductor circuit according to a third embodiment of the present disclosure.

FIG. 20 is a plan view of a semiconductor device according to the third embodiment of the present disclosure.

FIG. 21 is a bottom view of the semiconductor device shown in FIG. 20.

FIG. 22 is a cross-sectional view taken along line XXII-XXII in FIG. 20.

FIG. 23 is a cross-sectional view taken along line XXIII-XXIII in FIG. 20.

FIG. 24 is a cross-sectional view taken along line XXIV-XXIV in FIG. 20.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments for embodying the present disclosure will be described with reference to the accompanying drawings.

### First Embodiment (Semiconductor Circuit A10)

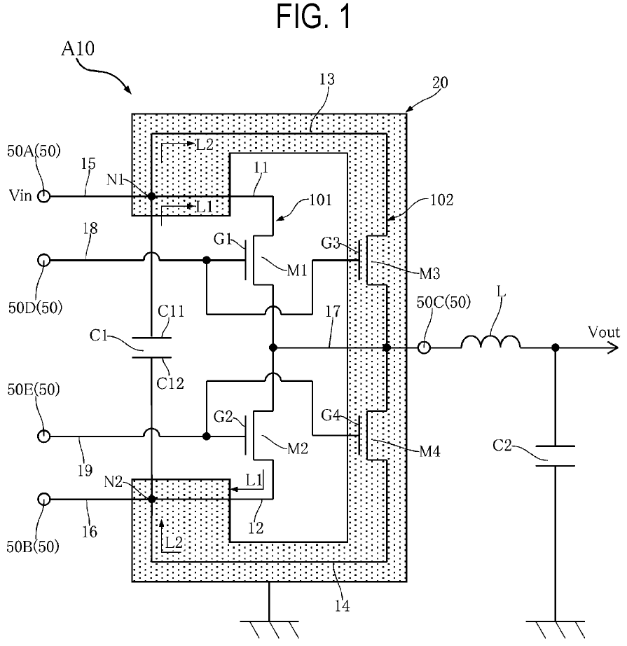

A semiconductor circuit A10 according to a first embodiment of the present disclosure will be described with reference to FIG. 1. The semiconductor circuit A10 constitutes a portion of a step-down DC-DC converter circuit. The semiconductor circuit A10 includes an input capacitor C1, a first arm circuit 101, a second arm circuit 102, a shield 20, a plurality of terminals 50, an inductor L, and an output capacitor C2. In FIG. 1, a portion corresponding to the shield 20 is shown as a region of plural points.

As shown in FIG. 1, the input capacitor C1 has a first electrode C11 and a second electrode C12. The first electrode C11 is a positive electrode of the input capacitor C1. The second electrode C12 is a negative electrode of the input capacitor C1. A capacitance of the input capacitor C1 is required to be relatively large. The input capacitor C1 is, for example, a ceramic capacitor.

As shown in FIG. 1, the first arm circuit 101 includes a first switching element M1 and a second switching element M2 that are connected in series with each other. As shown in FIG. 1, the second arm circuit 102 includes a third switching element M3 and a fourth switching element M4 that are connected in series with each other. Each of the first arm circuit 101 and the second arm circuit 102 constitutes a half-bridge circuit in the semiconductor circuit A10.

In the semiconductor circuit A10, the first switching element M1, the second switching element M2, the third switching element M3, and the fourth switching element M4 are n-channel type MOSFETs (Metal-Oxide-Semiconductor Field-Effect Transistors). However, the first switching element M1 and the second switching element M2 can be replaced with p-channel type MOSFETs. The present disclosure deals with a case where the first switching element M1, the second switching element M2, the third switching element M3, and the fourth switching element M4 are all n-channel type MOSFETs.

As shown in FIG. 1, the semiconductor circuit A10 includes a first node N1 and a second node N2 as constituent elements. The first node N1 corresponds to a start point of each of the first arm circuit 101 and the second arm circuit 102. The first electrode C11 of the input capacitor C1 is electrically connected to the first node N1. A potential of the first node N1 is equal to a potential of the first electrode C11. The second node N2 corresponds to an end point of each of the first arm circuit 101 and the second arm circuit 102. The second electrode C12 of the input capacitor C1 is electrically connected to the second node N2. A potential of the second node N2 is equal to a potential of the second electrode C12.

As shown in FIG. 1, in the first arm circuit 101, a drain of the first switching element M1 is electrically connected to the first electrode C11 of the input capacitor C1 via the first node N1. In addition, a source of the second switching element M2 is electrically connected to the second electrode C12 of the input capacitor C1 via the second node N2. Therefore, the first arm circuit 101 is connected in parallel with the input capacitor C1.

As shown in FIG. 1, in the second arm circuit 102, a drain of the third switching element M3 is electrically connected to the first electrode C11 of the input capacitor C1 via the first node N1. In addition, a source of the fourth switching element M4 is electrically connected to the second electrode C12 of the input capacitor C1 via the second node N2. Accordingly, the second arm circuit 102 is connected in parallel with the input capacitor C1.

As shown in FIG. 1, the first arm circuit 101 has a first path L1. The first path L1 corresponds to a conductive path of the first arm circuit 101 from the first node N1 to the second node N2. The second arm circuit 102 has a second path L2. The second path L2 corresponds to a conductive path of the second arm circuit 102 from the first node N1 to the second node N2. A length of the second path L2 is longer than a length of the first path L1.

As shown in FIG. 1, the first arm circuit 101 includes a first wiring 11 and a second wiring 12. The first wiring 11 electrically connects the first node N1 and the drain of the first switching element M1. The second wiring 12 electrically connects the second node N2 and the source of the second switching element M2. The first wiring 11 and the second wiring 12 are main elements of the first path L1.

As shown in FIG. 1, the second arm circuit 102 includes a third wiring 13 and a fourth wiring 14. The third wiring 13 electrically connects the first node N1 and the drain of the third switching element M3. The fourth wiring 14 electrically connects the second node N2 and the source of the fourth switching element M4. The third wiring 13 and the fourth wiring 14 are main elements of the second path L2. A length of the third wiring 13 is longer than a length of the first wiring 11. A length of the fourth wiring 14 is longer than a length of the second wiring 12.

As shown in FIG. 1, a first input wiring 15, a second input wiring 16, and an output wiring 17 are included in constituent elements of the semiconductor circuit A10. The first input wiring 15 is connected to the first node N1. Accordingly, the first input wiring 15 is electrically connected to the first electrode C11 of the input capacitor C1, the drain of the first switching element M1, and the drain of the third switching element M3. The second input wiring 16 is connected to the second node N2. Accordingly, the second input wiring 16 is electrically connected to the second electrode C12 of the input capacitor C1, the source of the second switching element M2, and the source of the fourth switching element M4. The output wiring 17 is electrically connected to the source of each of the first switching element M1 and the third switching element M3 and the drain of each of the second switching element M2 and the fourth switching element M4.

As shown in FIG. 1, a first gate wiring 18 and a second gate wiring 19 are included in the constituent elements of the semiconductor circuit A10. The first gate wiring 18 is electrically connected to a first gate G1 of the first switching element M1 and a third gate G3 of the third switching element M3. The second gate wiring 19 is electrically connected to a second gate G2 of the second switching element M2 and a fourth gate G4 of the fourth switching element M4.

As shown in FIG. 1, the plurality of terminals 50 includes a first input terminal 50A, a second input terminal 50B, an output terminal 50C, a first gate terminal 50D, and a second gate terminal 50E. The first input terminal 50A is electrically connected to the first input wiring 15. The second input terminal 50B is electrically connected to the second input wiring 16. An input voltage Vᵢₙ to be stepped-down is applied to the first input terminal 50A. The second input terminal 50B is a ground for the input voltage Vᵢₙ. The output terminal 50C is electrically connected to the output wiring 17. A voltage converted by driving the first switching element M1, the second switching element M2, the third switching element M3, and the fourth switching element M4 is output from the output terminal 50C.

The first gate terminal 50D is electrically connected to the first gate wiring 18. A gate voltage for operating the first gate G1 of the first switching element M1 and the third gate G3 of the third switching element M3 is applied to the first gate terminal 50D. The second gate terminal 50E is electrically connected to the second gate wiring 19. A gate voltage for operating the second gate G2 of the second switching element M2 and the fourth gate G4 of the fourth switching element M4 is applied to the second gate terminal 50E. The first gate terminal 50D and the second gate terminal 50E are connected to an external control circuit (not shown).

As shown in FIG. 1, the inductor L is electrically connected to the output terminal 50C. Accordingly, the inductor L is electrically connected, via the output wiring 17, to the source of each of the first switching element M1 and the third switching element M3 and the drain of each of the second switching element M2 and the fourth switching element M4.

As shown in FIG. 1, the output capacitor C2 is electrically connected to the inductor L. More specifically, a positive electrode of the output capacitor C2 is electrically connected to the inductor L. A negative electrode of the output capacitor C2 is externally grounded. In the semiconductor circuit A10, the inductor L and the output capacitor C2 constitute a low-pass filter.

Next, an operation of the semiconductor circuit A10 will be described. When the input voltage Vᵢₙ to be stepped-down is applied to the first input terminal 50A, the first switching element M1 and the third switching element M3 are driven. Thus, a pulsed input voltage Vᵢₙ is obtained at the output terminal 50C. At this time, the gate voltage is applied to the first gate terminal 50D based on PWM (Pulse Width Modulation) control. In this case, the input capacitor C1 contributes to stabilizing a waveform of the pulsed input voltage Vᵢₙ. Thereafter, the second switching element M2 and the fourth switching element M4 are driven. As a result, the pulsed input voltage Vᵢₙ is smoothed by the inductor L and the output capacitor C2, and is converted to a stepped-down output voltage Vₒᵤₜ. The output voltage Vₒᵤₜ is output to the outside. Therefore, the semiconductor circuit A10 takes a synchronous rectification method.

Next, the shield 20 included in the semiconductor circuit A10 will be described. As shown in FIG. 1, the shield 20 overlaps with at least a portion of the second arm circuit 102 in a plan view. The shield 20 is externally grounded. The shield 20 is a conductor. The shield 20 is made of a material containing metal.

As shown in FIG. 1, a length of the section of the shield 20 that overlaps with the second arm circuit 102 in a plan view and extends along the second path L2 is longer than a length of the shield 20 that overlaps with the first arm circuit 101 in a plan view and extends along the first path L1.

As shown in FIG. 1, in a plan view, the shield 20 overlaps with the entire second arm circuit 102 in a plan view. Accordingly, the shield 20 entirely overlaps with each of the third switching element M3, the fourth switching element M4, the third wiring 13, and the fourth wiring 14. In addition, in a plan view, the shield 20 also overlaps the first node N1, the second node N2, and the first wiring 11 and the second wiring 12 of the first arm circuit 101.

As shown in FIG. 1, the inductor L and the output capacitor C2 are located outside the shield 20 in a plan view.

### First Embodiment (Semiconductor Device B10)

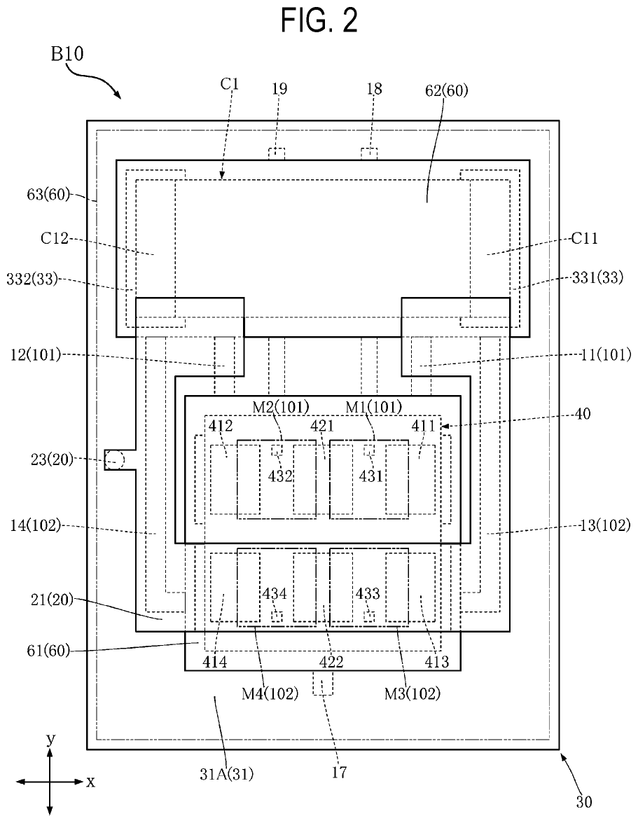

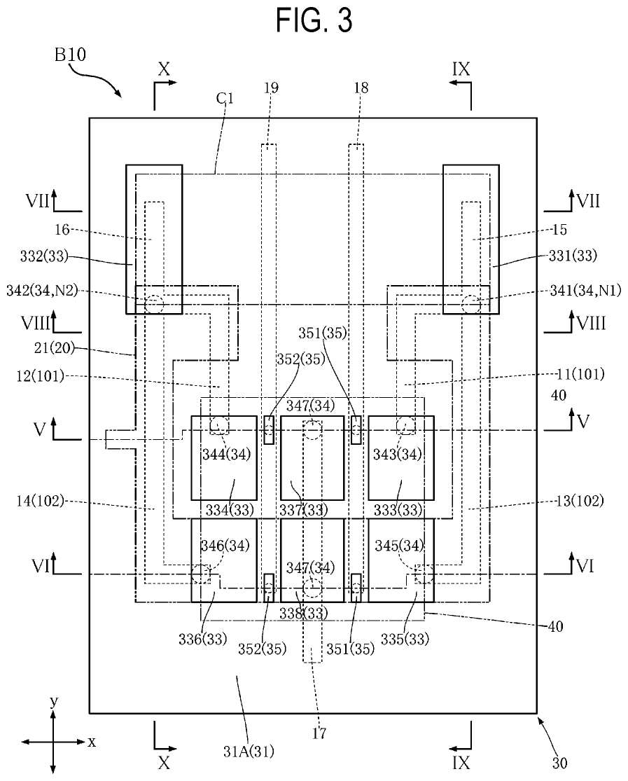

Next, a semiconductor device B10 according to the first embodiment of the present disclosure will be described with reference to FIGS. 2 to 10. The semiconductor device B10 is used in an electronic apparatus equipped with a step-down DC-DC converter. The semiconductor device B10 is surface-mounted on a wiring board of the electronic apparatus. The semiconductor device B10 includes the semiconductor circuit A10 (excluding the inductor L and the output capacitor C2), a base material 30, a semiconductor element 40, and a sealing resin 60. Here, in FIG. 2, for the sake of convenience of understanding, a third portion 63 of the sealing resin 60, which will be described later, is transparent. In FIG. 3, for the sake of convenience of understanding, the sealing resin 60 is omitted and the shield 20, the input capacitor C1, and the semiconductor element 40 are transparent. In FIG. 2, the transparent third portion 63 of the sealing resin 60 is indicated by an imaginary line (two-dot chain line). In FIG. 3, each of the transparent shield 20, the input capacitor C1, and the semiconductor element 40 is indicated by an imaginary line.

In the description of the semiconductor device B10, for the sake of convenience, a normal direction of a main surface 31A of a first insulating layer 31 of the base material 30, which will be described later, is called a “first direction z.” A direction orthogonal to the first direction z is called a “second direction x.” A direction orthogonal to both the first direction z and the second direction x is called a “third direction y.” “Viewed along the first direction z” corresponds to a “plan view.”

As shown in FIG. 2, the semiconductor element 40 includes the first switching element M1 and the second switching element M2 of the first arm circuit 101 included in the semiconductor circuit A10. In addition, the semiconductor element 40 includes the third switching element M3 and the fourth switching element M4 of the second arm circuit 102 included in the semiconductor circuit A10. Accordingly, the semiconductor element 40 constitutes a part of each of the first arm circuit 101 and the second arm circuit 102. The semiconductor element 40 is conductively bonded to the base material 30 by flip-chip mounting.

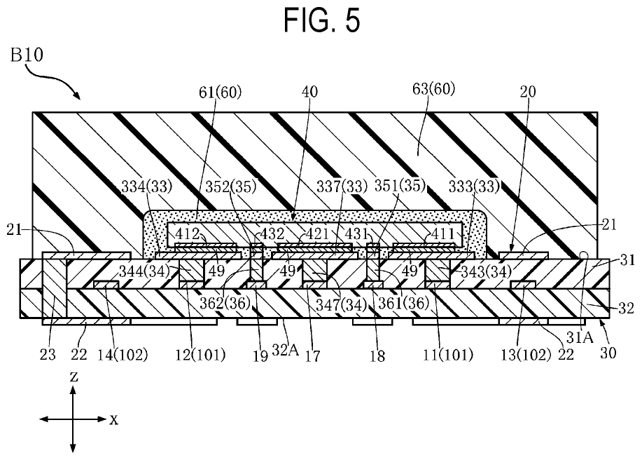

As shown in FIGS. 2 and 5, the semiconductor element 40 has a first input electrode 411, a second input electrode 412, and a first output electrode 421. The first input electrode 411, the second input electrode 412, and the first output electrode 421 face the base material 30. The first output electrode 421 is located between the first input electrode 411 and the second input electrode 412 in the second direction x. The first input electrode 411, the second input electrode 412, and the first output electrode 421 constitute a part of the first arm circuit 101. The first input electrode 411 is electrically connected to the drain of the first switching element M1. The second input electrode 412 is electrically connected to the source of the second switching element M2. The first output electrode 421 is electrically connected to a source of the first switching element M1 and a drain of the second switching element M2.

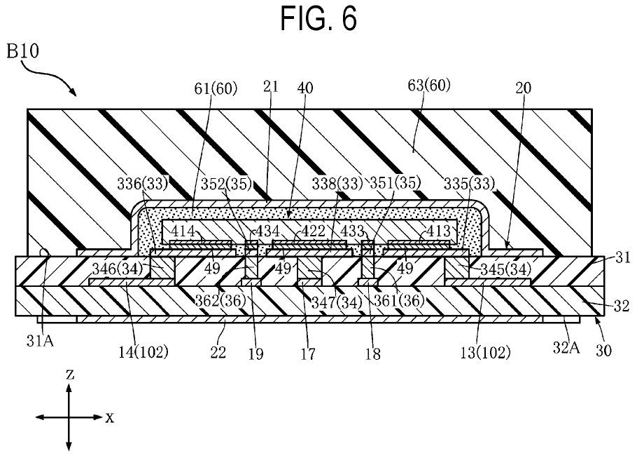

As shown in FIGS. 2 and 6, the semiconductor element 40 has a third input electrode 413, a fourth input electrode 414, and a second output electrode 422. The third input electrode 413, the fourth input electrode 414, and the second output electrode 422 face the base material 30. The third input electrode 413, the fourth input electrode 414, and the second output electrode 422 are located on the opposite side to the input capacitor C1 with respect to the first input electrode 411, the second input electrode 412, and the first output electrode 421 in the third direction y. The third input electrode 413 is located next to the first input electrode 411 in the third direction y. The fourth input electrode 414 is located next to the second input electrode 412 in the third direction y. The second output electrode 422 is located between the third input electrode 413 and the fourth input electrode 414 in the second direction x. The third input electrode 413, the fourth input electrode 414, and the second output electrode 422 constitute a part of the second arm circuit 102. The third input electrode 413 is electrically connected to the drain of the third switching element M3. The fourth input electrode 414 is electrically connected to the source of the fourth switching element M4. The second output electrode 422 is electrically connected to a source of the third switching element M3 and a drain of the fourth switching element M4.

As shown in FIGS. 2 and 5, the semiconductor element 40 has a first gate electrode 431 and a second gate electrode 432. The first gate electrode 431 is located between the first input electrode 411 and the first output electrode 421 in the second direction x. The second gate electrode 432 is located between the second input electrode 412 and the first output electrode 421 in the second direction x. The first gate electrode 431 and the second gate electrode 432 constitute a part of the first arm circuit 101. The first gate electrode 431 is electrically connected to the first gate G1 of the first switching element M1. The second gate electrode 432 is electrically connected to the second gate G2 of the second switching element M2.

As shown in FIGS. 2 and 6, the semiconductor element 40 has a third gate electrode 433 and a fourth gate electrode 434. The third gate electrode 433 is located between the third input electrode 413 and the second output electrode 422 in the second direction x. The fourth gate electrode 434 is located between the fourth input electrode 414 and the second output electrode 422 in the second direction x. The third gate electrode 433 and the fourth gate electrode 434 constitute a part of the second arm circuit 102. The third gate electrode 433 is electrically connected to the third gate G3 of the third switching element M3. The fourth gate electrode 434 is electrically connected to the fourth gate G4 of the fourth switching element M4.

The base material 30 is mounted with the semiconductor circuit A10 (excluding the inductor L and the output capacitor C2). The base material 30 is, for example, a PWB (Printed Wiring Board). As shown in FIGS. 3 to 10, the base material 30 includes the first insulating layer 31, a second insulating layer 32, a plurality of pad layers 33, a plurality of contact layers 34, a plurality of gate pad layers 35, a plurality of gate contact layers 36, and a plurality of interconnection wiring layers 39.

As shown in FIGS. 5 to 7, the first insulating layer 31 is located between the second insulating layer 32 and the input capacitor C1 and between the second insulating layer 32 and the semiconductor element 40 in the first direction z. The first insulating layer 31 is stacked on the second insulating layer 32. The first insulating layer 31 is made of a material containing, for example, epoxy resin. The first insulating layer 31 has the main surface 31A facing in the first direction z. The main surface 31A faces the input capacitor C1 and the semiconductor element 40.

As shown in FIGS. 5 to 10, the second insulating layer 32 has a back surface 32A facing opposite to the main surface 31A of the first insulating layer 31 in the first direction z. The second insulating layer 32 is made of a material containing, for example, epoxy resin.

As shown in FIGS. 5 to 10, the first wiring 11, the second wiring 12, the third wiring 13, the fourth wiring 14, the first input wiring 15, the second input wiring 16, the output wiring 17, the first gate wiring 18, and the second gate wiring 19, which constitute the semiconductor circuit A10, are sandwiched between the first insulating layer 31 and the second insulating layer 32. When viewed in the first direction z, these wirings are located inward of a periphery of each of the first insulating layer 31 and the second insulating layer 32. Therefore, these wirings are accommodated in the base material 30. Here, the first wiring 11 and the second wiring 12 constitute a part of the first arm circuit 101. The third wiring 13 and the fourth wiring 14 constitute a part of the second arm circuit 102. Accordingly, in the semiconductor device B10, a part of each of first arm circuit 101 and the second arm circuit 102 is accommodated in the base material 30. The first wiring 11, the second wiring 12, the third wiring 13, the fourth wiring 14, the first input wiring 15, the second input wiring 16, the output wiring 17, the first gate wiring 18, and the second gate wiring 19 are made of a material containing, for example, copper (Cu).

As shown in FIG. 3 and FIGS. 5 to 7, the plurality of pad layers 33 is disposed on the main surface 31A of the first insulating layer 31. The plurality of pad layers 33 is made of a material containing, for example, copper. The plurality of pad layers 33 includes a first pad 331, a second pad 332, a third pad 333, a fourth pad 334, a fifth pad 335, a sixth pad 336, a seventh pad 337, and an eighth pad 338.

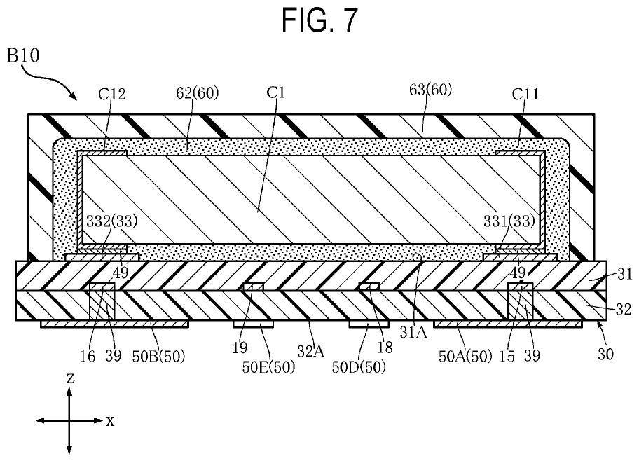

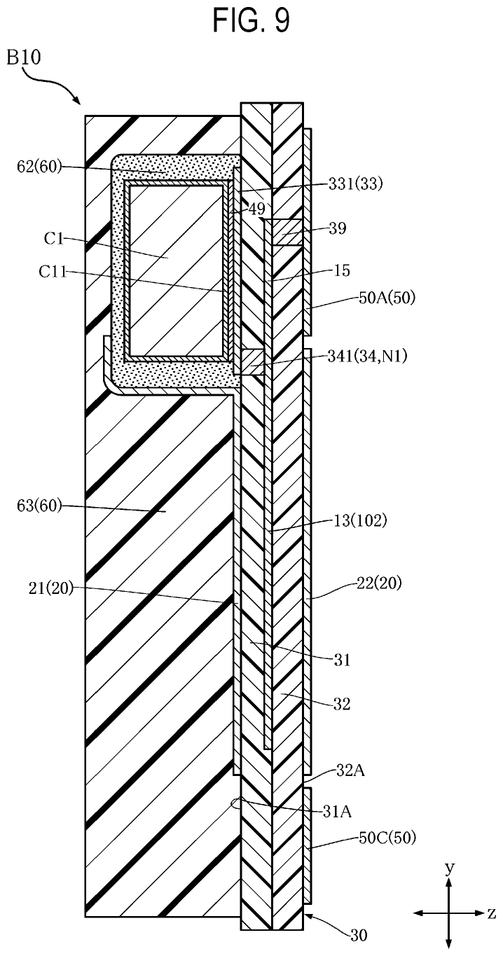

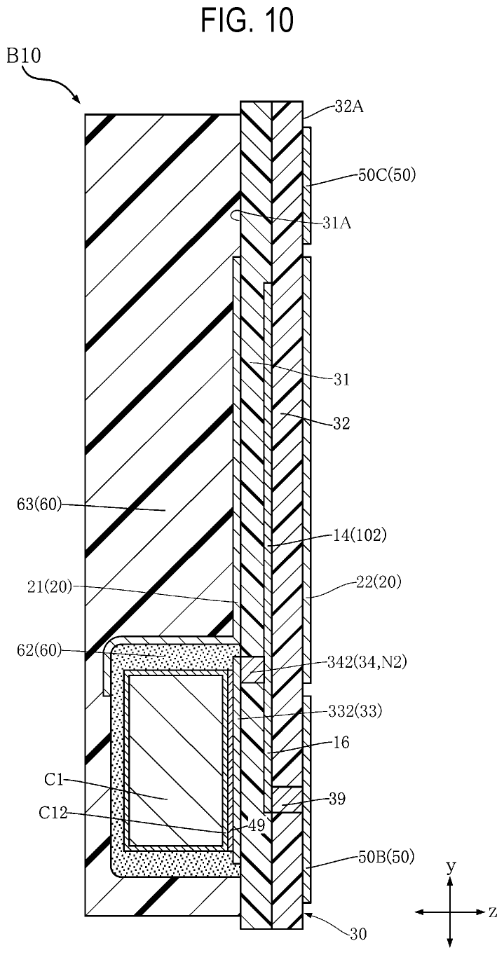

As shown in FIG. 3, the first pad 331 and the second pad 332 are located apart from each other in the second direction x. The first pad 331 overlaps with the first input wiring 15 when viewed in the first direction z. The second pad 332 overlaps with the second input wiring 16 when viewed in the first direction z. As shown in FIGS. 7 and 9, the first electrode C11 of the input capacitor C1 is conductively bonded to the first pad 331 via a bonding layer 49. The bonding layer 49 is, for example, solder. As shown in FIGS. 7 and 10, the second electrode C12 of the input capacitor C1 is conductively bonded to the second pad 332 via the bonding layer 49. Accordingly, the input capacitor C1 is conductively bonded to the base material 30.

As shown in FIG. 3, the third pad 333, the fourth pad 334, and the seventh pad 337 are arranged along the second direction x. The seventh pad 337 is located between the third pad 333 and the fourth pad 334 in the second direction x. The third pad 333 overlaps with the first wiring 11 when viewed in the first direction z. The fourth pad 334 overlaps with the second wiring 12 when viewed in the first direction z. The seventh pad 337 overlaps with the output wiring 17 when viewed in the first direction z.

As shown in FIG. 5, the first input electrode 411 of the semiconductor element 40 is conductively bonded to the third pad 333 via the bonding layer 49. The second input electrode 412 of the semiconductor element 40 is conductively bonded to the fourth pad 334 via the bonding layer 49. The first output electrode 421 of the semiconductor element 40 is conductively bonded to the seventh pad 337 via the bonding layer 49.

As shown in FIG. 3, the fifth pad 335, the sixth pad 336, and the eighth pad 338 are located on the opposite side to the first pad 331 and the second pad 332 with respect to the third pad 333, the fourth pad 334, and the seventh pad 337 in the third direction y. The fifth pad 335, the sixth pad 336, and the eighth pad 338 are arranged along the second direction x. The fifth pad 335 is located next to the third pad 333 in the third direction y and overlaps with the third wiring 13 when viewed in the first direction z. The sixth pad 336 is located next to the fourth pad 334 in the third direction y and overlaps with the fourth wiring 14 when viewed in the first direction z. The eighth pad 338 is located between the fifth pad 335 and the sixth pad 336 in the second direction x and overlaps with the output wiring 17 when viewed in the first direction z.

As shown in FIG. 6, the third input electrode 413 of the semiconductor element 40 is conductively bonded to the fifth pad 335 via the bonding layer 49. The fourth input electrode 414 of the semiconductor element 40 is conductively bonded to the sixth pad 336 via the bonding layer 49. The second output electrode 422 of the semiconductor element 40 is conductively bonded to the eighth pad 338 via the bonding layer 49.

As shown in FIGS. 5, 6, 9, and 10, the plurality of contact layers 34 is accommodated in the first insulating layer 31. The plurality of contact layers 34 is made of a material containing, for example, copper. The plurality of contact layers 34 includes a first contact 341, a second contact 342, a third contact 343, a fourth contact 344, a fifth contact 345, a sixth contact 346, and two seventh contacts 347.

The first contact 341 corresponds to the first node N1 constituting the semiconductor circuit A10. As shown in FIGS. 3 and 9, the first contact 341 is connected to the first pad 331 and the first input wiring 15. As a result, the first input wiring 15 is electrically connected to the first electrode C11 of the input capacitor C1.

As shown in FIG. 3, the first contact 341 is connected to the first pad 331 and the first wiring 11. As shown in FIG. 5, the third contact 343 is connected to the third pad 333 and the first wiring 11. As a result, the drain of the first switching element M1 of the first arm circuit 101 is electrically connected to the first input wiring 15 and the first electrode C11 of the input capacitor C1. Accordingly, the first wiring 11 electrically connects the first contact 341 and the drain of the first switching element M1.

As shown in FIGS. 3 and 9, the first contact 341 is connected to the first pad 331 and the third wiring 13. As shown in FIG. 6, the fifth contact 345 is connected to the fifth pad 335 and the third wiring 13. As a result, the drain of the third switching element M3 of the second arm circuit 102 is electrically connected to the first input wiring 15 and the first electrode C11 of the input capacitor C1. Accordingly, the third wiring 13 electrically connects the first contact 341 and the drain of the third switching element M3.

The second contact 342 corresponds to the second node N2 constituting the semiconductor circuit A10. As shown in FIGS. 3 and 10, the second contact 342 is connected to the second pad 332 and the second input wiring 16. As a result, the second input wiring 16 is electrically connected to the second electrode C12 of the input capacitor C1.

As shown in FIG. 3, the second contact 342 is connected to the second pad 332 and the second wiring 12. As shown in FIG. 5, the fourth contact 344 is connected to the fourth pad 334 and the second wiring 12. As a result, the source of the second switching element M2 of the first arm circuit 101 is electrically connected to the second input wiring 16 and the second electrode C12 of the input capacitor C1. Accordingly, the second wiring 12 electrically connects the second contact 342 and the source of the second switching element M2.

As shown in FIGS. 3 and 10, the second contact 342 is connected to the second pad 332 and the fourth wiring 14. As shown in FIG. 6, the sixth contact 346 is connected to the sixth pad 336 and the fourth wiring 14. As a result, the source of the fourth switching element M4 of the second arm circuit 102 is electrically connected to the second input wiring 16 and the second electrode C12 of the input capacitor C1. Accordingly, the fourth wiring 14 electrically connects the second contact 342 and the source of the fourth switching element M4.

As shown in FIGS. 3, 5, and 6, the two seventh contacts 347 are individually connected to the seventh pad 337 and the eighth pad 338. Further, the two seventh contacts 347 are connected to the output wiring 17. As a result, the output wiring 17 is electrically connected to the source of each of the first switching element M1 and the third switching element M3 and the drain of each of the second switching element M2 and the fourth switching element M4.

As shown in FIGS. 3, 5, and 6, the plurality of gate pad layers 35 is disposed on the main surface 31A of the first insulating layer 31. The plurality of gate pad layers 35 is made of a material containing, for example, copper. The plurality of gate pad layers 35 includes two first gate pads 351 and two second gate pads 352.

As shown in FIG. 3, the two first gate pads 351 are located apart from each other in the third direction y. The two first gate pads 351 are located between the third pad 333 and the seventh pad 337 and between the fifth pad 335 and the eighth pad 338 in the second direction x. The two first gate pads 351 overlap with the first gate wiring 18 when viewed in the first direction z. As shown in FIGS. 5 and 6, the first gate electrode 431 and the third gate electrode 433 of the semiconductor element 40 are individually and conductively bonded to the two first gate pads 351 via the bonding layer 49.

As shown in FIG. 3, the two second gate pads 352 are located apart from each other in the third direction y. The two second gate pads 352 are located between the fourth pad 334 and the seventh pad 337 and between the sixth pad 336 and the eighth pad 338 in the second direction x. The two second gate pads 352 overlap with the second gate wiring 19 when viewed in the first direction z. As shown in FIGS. 5 and 6, the second gate electrode 432 and the fourth gate electrode 434 of the semiconductor element 40 are individually and conductively bonded to the two second gate pads 352 via the bonding layer 49.

As shown in FIGS. 5 and 6, the plurality of gate contact layers 36 is accommodated in the first insulating layer 31. The plurality of gate contact layers 36 is made of a material containing, for example, copper. The plurality of gate contact layers 36 includes two first gate contacts 361 and two second gate contacts 362.

As shown in FIGS. 5 and 6, the two first gate contacts 361 are individually connected to the two first gate pads 351. Further, the two first gate contacts 361 are connected to the first gate wiring 18. As a result, the first gate wiring 18 is electrically connected to the first gate G1 of the first switching element M1 of the first arm circuit 101 and the third gate G3 of the third switching element M3 of the second arm circuit 102.

As shown in FIGS. 5 and 6, the two second gate contacts 362 are individually connected to the two second gate pads 352. Further, the two second gate contacts 362 are connected to the second gate wiring 19. As a result, the second gate wiring 19 is electrically connected to the second gate G2 of the second switching element M2 of the first arm circuit 101 and the fourth gate G4 of the fourth switching element M4 of the second arm circuit 102.

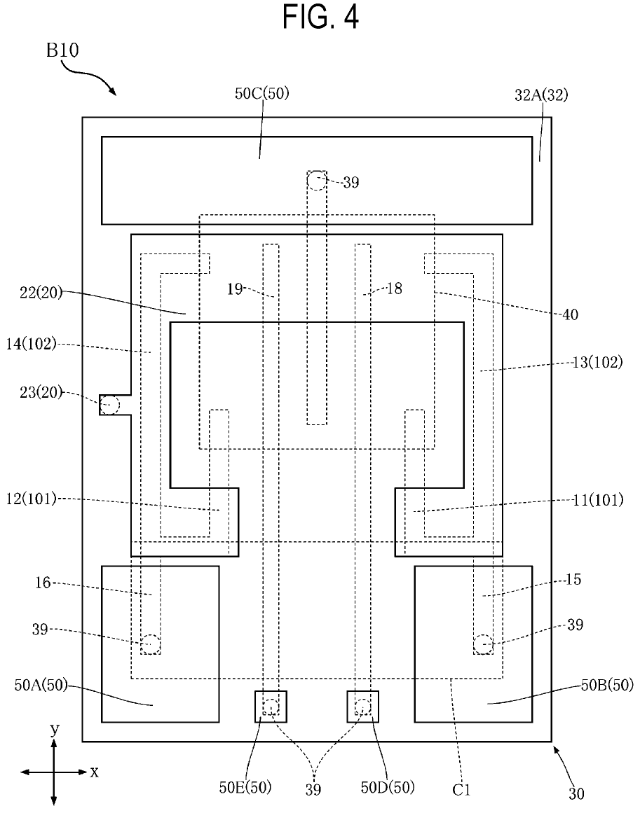

As shown in FIGS. 4, 9, and 10, the plurality of terminals 50 included in the semiconductor circuit A10 is arranged on the back surface 32A of the second insulating layer 32. The plurality of terminals 50 is exposed to the outside from the back surface 32A. The plurality of terminals 50 is made of a material containing, for example, copper.

As shown in FIG. 4, the plurality of terminals 50 includes the first input terminal 50A, the second input terminal 50B, the output terminal 50C, the first gate terminal 50D, and the second gate terminal 50E. The first input terminal 50A and the second input terminal 50B are located on one side of the base material 30 in the third direction y. The first input terminal 50A and the second input terminal 50B are separated from each other in the second direction x. The first input terminal 50A overlaps with the input capacitor C1 and the first input wiring 15 when viewed in the first direction z. The second input terminal 50B overlaps with the input capacitor C1 and the second input wiring 16 when viewed in the first direction z.

As shown in FIG. 4, the output terminal 50C is located on the opposite side to the first input terminal 50A and the second input terminal 50B with respect to a second shield portion 22 of the shield 20, which will be described later, in the third direction y. The output terminal 50C overlaps with the output wiring 17 when viewed in the first direction z. The first gate terminal 50D and the second gate terminal 50E are located between the first input terminal 50A and the second input terminal 50B in the second direction x. The first gate terminal 50D overlaps with the first gate wiring 18 when viewed in the first direction z. The second gate terminal 50E overlaps with the second gate wiring 19 when viewed in the first direction z.

As shown in FIGS. 7, 9, and 10, the plurality of interconnection wiring layers 39 is accommodated in the second insulating layer 32. The plurality of interconnection wiring layers 39 is made of a material containing, for example, copper. Each of the plurality of interconnection wiring layers 39 is individually connected to the plurality of terminals 50. Further, the plurality of interconnection wiring layers 39 is individually connected to the first input wiring 15, the second input wiring 16, the output wiring 17, the first gate wiring 18, and the second gate wiring 19.

As a result, the first input terminal 50A is electrically connected to the first electrode C11 of the input capacitor C1, the drain of the first switching element M1 of the first arm circuit 101, and the drain of the third switching element M3 of the second arm circuit 102 via the first input wiring 15. The second input terminal 50B is electrically connected to the second electrode C12 of the input capacitor C1, the source of the second switching element M2 of the first arm circuit 101, and the source of the fourth switching element M4 of the second arm circuit 102 via the second input wiring 16. The output terminal 50C is electrically connected to the source of each of the first switching element M1 and the third switching element M3 and the drain of each of the second switching element M2 and the fourth switching element M4 via the output wiring 17. The first gate terminal 50D is electrically connected to the first gate G1 of the first switching element M1 and the third gate G3 of the third switching element M3 via the first gate wiring 18. The second gate terminal 50E is electrically connected to the second gate G2 of the second switching element M2 and the fourth gate G4 of the fourth switching element M4 via the second gate wiring 19. Therefore, each of the plurality of terminals 50 is electrically connected to at least one of the input capacitor C1, the first arm circuit 101, or the second arm circuit 102.

As shown in FIGS. 5 to 10, the sealing resin 60 is disposed on the main surface 31A of the first insulating layer 31. The sealing resin 60 has electrical insulation property. The sealing resin 60 includes a first portion 61, a second portion 62, and a third portion 63. Each of the first portion 61, the second portion 62, and the third portion 63 is in contact with the main surface 31A of the first insulating layer 31.

As shown in FIGS. 2, 5, and 6, the first portion 61 covers the semiconductor element 40. As shown in FIGS. 5 and 6, the first portion 61 further covers the third pad 333, the fourth pad 334, the fifth pad 335, the sixth pad 336, the seventh pad 337, the eighth pad 338, and the plurality of gate pad layers 35.

As shown in FIGS. 2, 7, 9, and 10, the second portion 62 covers the input capacitor C1, the first pad 331, and the second pad 332. The second portion 62 is separated from the first portion 61.

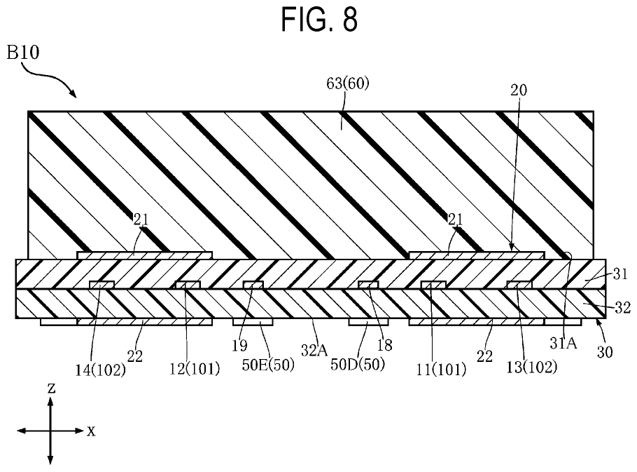

As shown in FIGS. 5 to 10 (excluding FIG. 8), the third portion 63 covers the first portion 61 and the second portion 62. A glass transition point of the third portion 63 is lower than a glass transition point of each of the first portion 61 and the second portion 62.

As shown in FIGS. 2 and 4, the shield 20 included in the semiconductor circuit A10 includes a first shield portion 21, the second shield portion 22, and an interconnection portion 23. The shield 20 is made of a material containing metal.

As shown in FIGS. 2, 5, 6, 9, and 10, the first shield portion 21 covers a portion of the main surface 31A of the first insulating layer 31 and a portion of each of the first portion 61 and the second portion 62 of the sealing resin 60. In addition, the first shield portion 21 is covered with the third portion 63 of the sealing resin 60. A portion of the first shield portion 21 that covers the portion of the first portion 61 is sandwiched between the first portion 61 and the third portion 63. A portion of the first shield portion 21 that covers the portion of the second portion 62 is sandwiched between the second portion 62 and the third portion 63. Accordingly, the portion of the first shield portion 21 that covers the portion of each of the first portion 61 and the second portion 62 is accommodated in the sealing resin 60.

As shown in FIGS. 4, 5, 6, 9, and 10, the second shield portion 22 covers a portion of the back surface 32A of the second insulating layer 32. The second shield portion 22 is exposed to the outside from the back surface 32A.

As shown in FIGS. 2 and 4, each of the first shield portion 21 and the second shield portion 22 overlaps with an entirety of each of the third switching element M3, the fourth switching element M4, the third wiring 13, the fourth wiring 14, the first contact 341, and the second contact 342 when viewed in the first direction z. Accordingly, the shield 20 overlaps the entire second arm circuit 102 in a plan view. In addition, each of the first shield portion 21 and the second shield portion 22 overlaps with a part of each of the first wiring 11, the second wiring 12, and the input capacitor C1 when viewed in the first direction z.

As shown in FIG. 5, the interconnection portion 23 is accommodated in the first insulating layer 31 and the second insulating layer 32. The interconnection part 23 is connected to the first shield portion 21 and the second shield portion 22. As a result, the first shield portion 21 and the second shield portion 22 are electrically connected to each other. When mounting the semiconductor device B10 on a wiring board, the second shield portion 22 is externally grounded.

Next, operative effects of the semiconductor circuit A10 and the semiconductor device B10 will be described.

The semiconductor circuit A10 includes the input capacitor C1, the first arm circuit 101 including the first switching element M1 and the second switching element M2, the second arm circuit 102 including the third switching element M3 and the fourth switching element M4, and the shield 20. The shield 20 overlaps with at least a portion of the second arm circuit 102 in a plan view and is externally grounded. The length of the second path L2 of the second arm circuit 102 is longer than the length of the first path L1 of the first arm circuit 101. A length of a section of the shield 20 that overlaps with the second arm circuit 102 in a plan view and extends along the second path L2 is longer than a length of a section of the shield 20 that overlaps with the first arm circuit 101 in a plan view and extends along the first path L1. By adopting this configuration, in the semiconductor circuit A10, since a length of a conductive path of the second arm circuit 102 is longer than a length of a conductive path of the first arm circuit 101, a larger magnetic field is generated in the second arm circuit 102 than in the first arm circuit 101. In this case, a magnitude of a magnetic field suppressed by the shield 20 is larger in the second arm circuit 102 than in the first arm circuit 101. As a result, since an effect of mutual cancellation of magnetic fields between the first arm circuit 101 and the second arm circuit 102 is exhibited, a degree of noise generated from each of the first arm circuit 101 and the second arm circuit 102 approaches an equivalent state. Accordingly, according to this configuration, in the semiconductor circuit A10, it is possible to reduce influence of noise caused by a half-bridge circuit that includes a plurality of arm circuits.

In the semiconductor circuit A10, the shield 20 overlaps with the entire second arm circuit 102 in a plan view. By adopting this configuration, since a total amount of magnetic field generated from the second arm circuit 102 is suppressed, the degree of noise generated from each of the first arm circuit 101 and the second arm circuit 102 can approach a more equivalent state.

In the semiconductor circuit A10, the shield 20 overlaps with each of the first wiring 11 and the second wiring 12 of the first arm circuit 101 in a plan view. By adopting this configuration, the total amount of magnetic field generated from the second arm circuit 102 and a portion of magnetic field generated from the first arm circuit 101 are suppressed. As a result, the degree of noise generated from each of the first arm circuit 101 and the second arm circuit 102 can also approach an equivalent state.

The semiconductor circuit A10 further includes the inductor L which is electrically connected to the first switching element M1, the second switching element M2, the third switching element M3, and the fourth switching element M4, and the output capacitor C2 which is electrically connected to the inductor L. The inductor L and the output capacitor C2 are located outside the shield 20 in a plan view. By adopting this configuration, in the semiconductor circuit A10, it is possible to achieve efficient arrangement of the shield 20 while suppressing noise generated from each of the inductor L and the output capacitor C2 from reaching the first arm circuit 101 and the second arm circuit 102.

The semiconductor device B10 includes the base material 30 on which the semiconductor circuit A10 is mounted. A part of each of the first arm circuit 101 and the second arm circuit 102 is accommodated in the base material 30. By adopting this configuration, influence of noise on each of the first arm circuit 101 and the second arm circuit 102 can be reduced by the base material 30.

The semiconductor device B10 further includes the semiconductor element 40 including the first switching element M1, the second switching element M2, the third switching element M3, and the fourth switching element M4. The semiconductor element 40 is conductively bonded to the base material 30. By adopting this configuration, each of the first arm circuit 101 and the second arm circuit 102 becomes more compact. This contributes to miniaturization of the semiconductor device B10.

The base material 30 has the main surface 31A facing the semiconductor element 40 in the first direction z and the back surface 32A facing the opposite side to the main surface 31A in the first direction z. The semiconductor device B10 further includes the plurality of terminals 50 exposed to the outside from the back surface 32A. Each of the plurality of terminals 50 is electrically connected to any one of the input capacitor C1, the first arm circuit 101, and the second arm circuit 102. By adopting this configuration, the semiconductor device B10 can be surface-mounted on a wiring board.

The semiconductor device B10 further includes the sealing resin 60 that covers at least the semiconductor element 40. A part of the shield 20 is accommodated in the sealing resin 60. By adopting this configuration, the part of the shield 20 together with the semiconductor element 40 can be protected from external factors.

### Second Embodiment (Semiconductor Circuit A20)

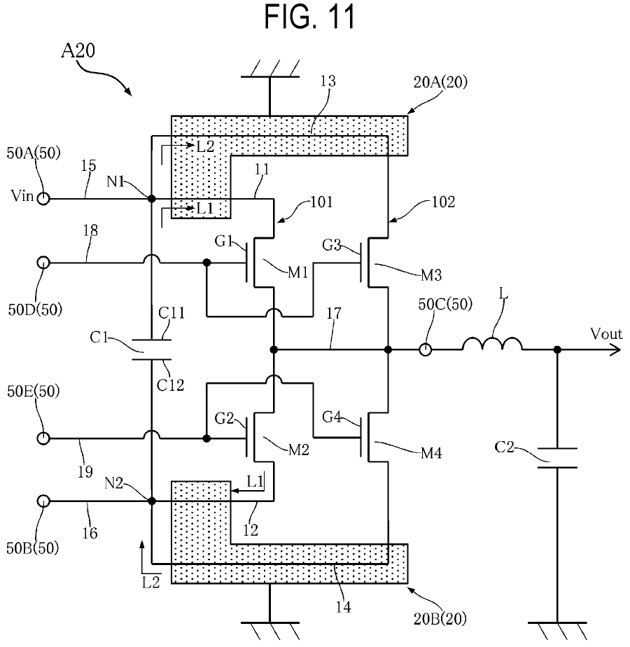

A semiconductor circuit A20 according to a second embodiment of the present disclosure will be described with reference to FIG. 11. In this figure, elements that are the same as or similar to those of the above-described semiconductor circuit A10 are denoted by the same reference numerals, and duplicate explanation thereof will be omitted.

In the semiconductor circuit A20, a configuration of the shield 20 is different from the configuration of the shield 20 in the semiconductor circuit A10.

As shown in FIG. 11, the shield 20 includes a first shield 20A and a second shield 20B, which are separated from each other. Each of the first shield 20A and the second shield 20B is externally grounded. In a plan view, the first shield 20A overlaps with the first wiring 11 of the first arm circuit 101 and the third wiring 13 of the second arm circuit 102. In a plan view, the second shield 20B overlaps with the second wiring 12 of the first arm circuit 101 and the fourth wiring 14 of the second arm circuit 102. However, in a plan view, the third switching element M3 and the fourth switching element M4 of the second arm circuit 102 are located outside the first shield 20A and the second shield 20B, respectively.

As shown in FIG. 11, a length of a section of the first shield 20A that overlaps with the second arm circuit 102 in a plan view and extends along the second path L2 is longer than a length of a section of the first shield 20A that overlaps with the first arm circuit 101 in a plan view and extends along the first path L1. In addition, a length of a section of the second shield 20B that overlaps with the second arm circuit 102 in a plan view and extends along the second path L2 is longer than a length of a section of the second shield 20B that overlaps with the first arm circuit 101 in a plan view and extends along the first path L1.

### Second Embodiment (Semiconductor Device B20)

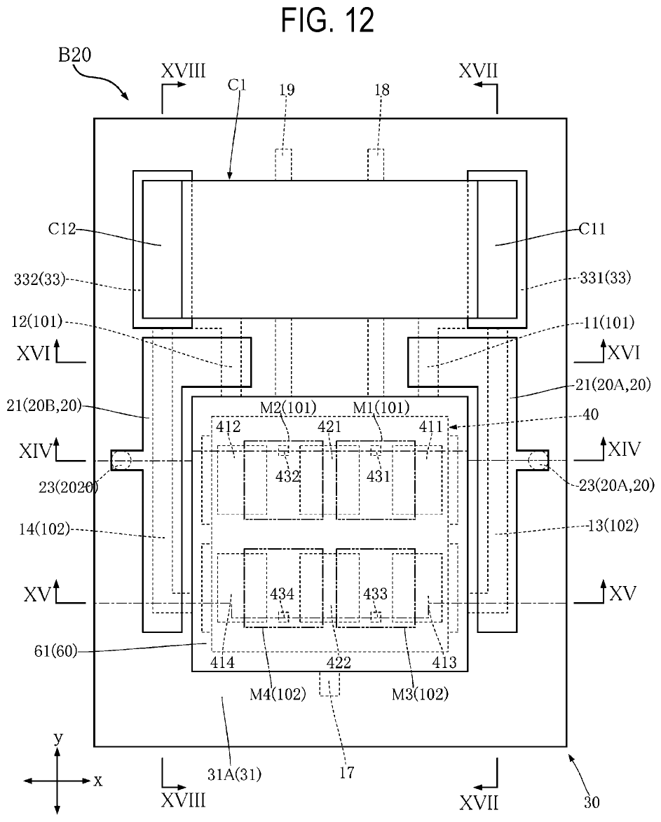

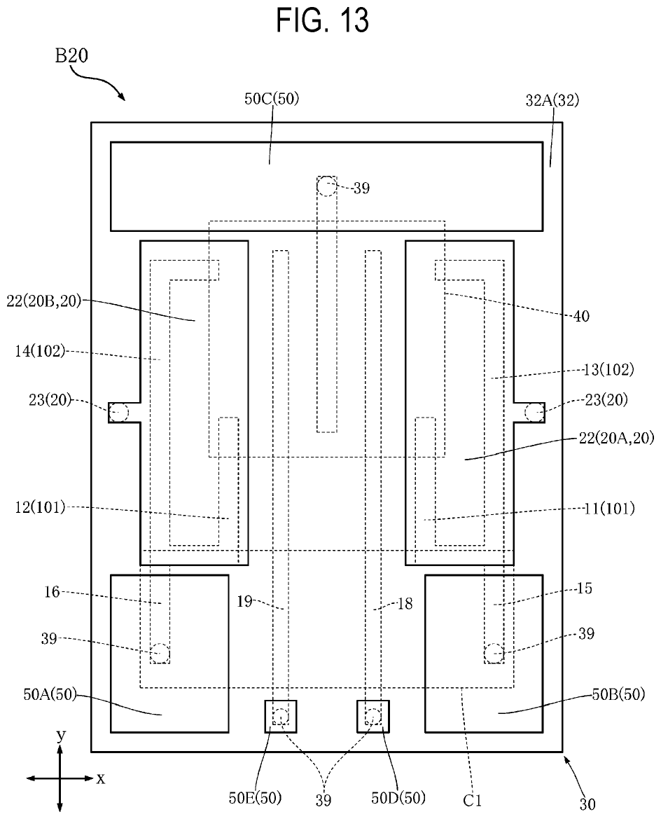

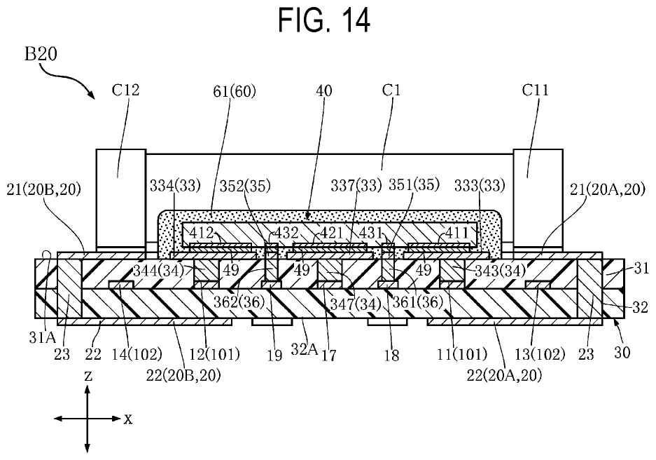

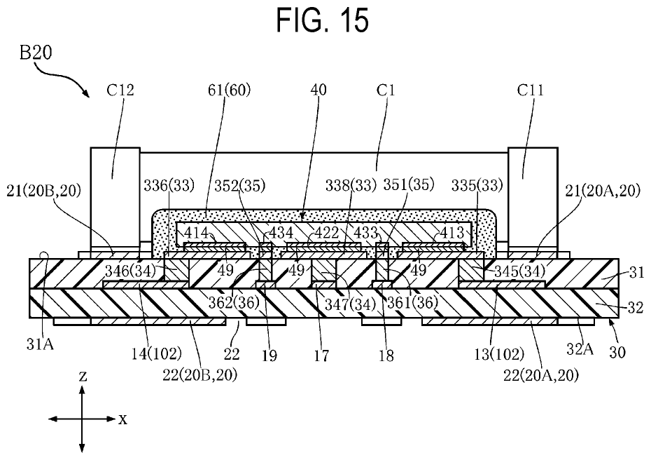

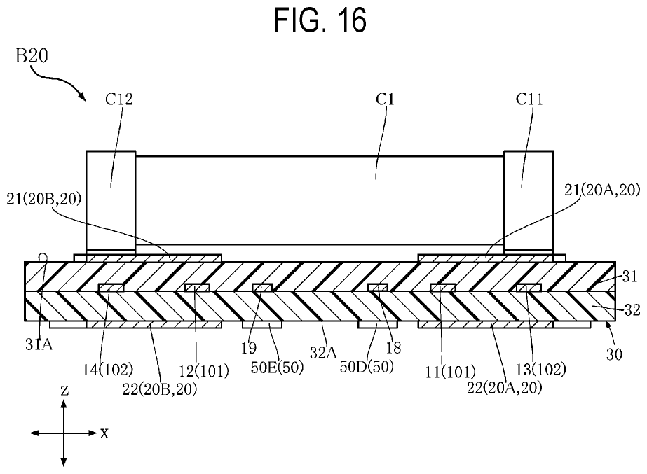

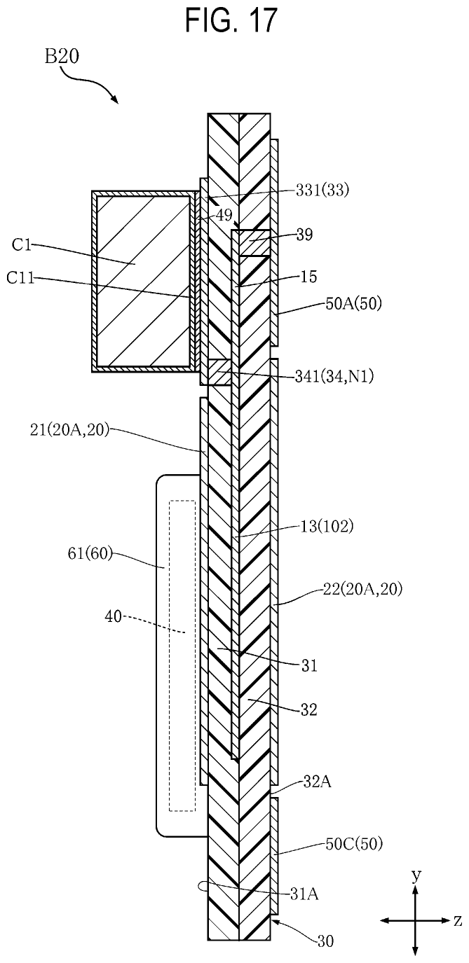

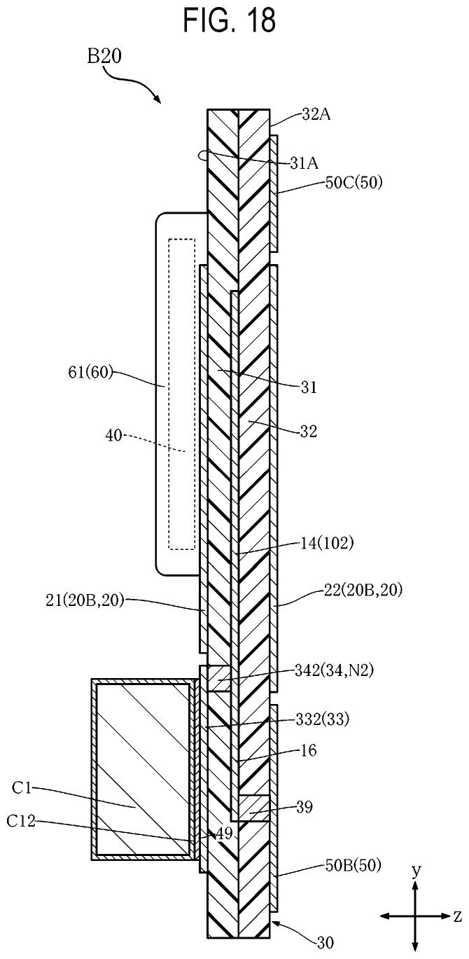

Next, a semiconductor device B20 according to the second embodiment of the present disclosure will be described with reference to FIGS. 12 to 18. In these figures, elements that are the same as or similar to those of the above-described semiconductor device B10 are denoted by the same reference numerals, and duplicate explanation thereof will be omitted.

The semiconductor device B20 includes the semiconductor circuit A20 (excluding the inductor L and the output capacitor C2) instead of the semiconductor circuit A10. Accordingly, in the semiconductor device B20, configurations of the shield 20 and the sealing resin 60 are different from the configurations of the shield 20 and the sealing resin 60 in the semiconductor device B10.

As shown in FIGS. 12 to 18, the shield 20 includes the first shield 20A and the second shield 20B, which are separated from each other in the second direction x. Each of the first shield 20A and the second shield 20B has a first shield portion 21, a second shield portion 22, and an interconnection portion 23. When viewed in the first direction z, each of the first shield portion 21 and the second shield portion 22 of the first shield 20A overlaps with the first wiring 11 and the third wiring 13 constituting the semiconductor circuit A20. When viewed in the first direction z, each of the first shield portion 21 and the second shield portion 22 of the second shield 20B overlaps with the second wiring 12 and the fourth wiring 14 constituting the semiconductor circuit A20. When viewed in the first direction z, each of the first shield 20A and the second shield 20B is separated from the input capacitor C1 and the semiconductor element 40.

As shown in FIG. 12 and FIGS. 14 to 18, the sealing resin 60 includes only the first portion 61. Therefore, the first portion 61 and the input capacitor C1 are exposed to the outside. In addition, the first shield portion 21 of each of the first shield 20A and the second shield 20B is exposed to the outside from the main surface 31A of the first insulating layer 31.

Next, operative effects of the semiconductor circuit A20 will be described.

The semiconductor circuit A20 includes the input capacitor C1, the first arm circuit 101 including the first switching element M1 and the second switching element M2, the second arm circuit 102 including the third switching element M3 and the fourth switching element M4, and the shield 20. The shield 20 overlaps with at least a part of the second arm circuit 102 in a plan view and is externally grounded. The length of the second path L2 of the second arm circuit 102 is longer than the length of the first path L1 of the first arm circuit 101. The length of the section of the shield 20 that overlaps with the second arm circuit 102 in a plan view and extends along the second path L2 is longer than the length of the section of the shield 20 that overlaps with the first arm circuit 101 in a plan view and extends along the first path L1. Accordingly, according to this configuration, even in the semiconductor circuit A20, it is possible to reduce influence of noise caused by a configuration of a half-bridge circuit that includes a plurality of arm circuits.

The semiconductor circuit A20 includes the first shield 20A and the second shield 20B, which are separated from each other. In a plan view, the first shield 20A overlaps with the third wiring 13 of the second arm circuit 102. In a plan view, the second shield 20B overlaps with the fourth wiring 14 of the second arm circuit 102. By adopting this configuration, a magnetic field generated from a wiring corresponding to a difference between the length of the conductive path of the first arm circuit 101 and the length of the conductive path of the second arm circuit 102 can be locally suppressed by the shield 20. This configuration is useful for improving efficiency of the arrangement of the shield 20 when the length of the conductive path of the second arm circuit 102 is relatively longer than the length of the conductive path of the first arm circuit 101.

In the semiconductor circuit A20, in a plan view, the first shield 20A overlaps with the first wiring 11 of the first arm circuit 101. In a plan view, the second shield 20B overlaps with the second wiring 12 of the first arm circuit 101. By adopting this configuration, a magnetic field generated from each of a wiring corresponding to the length of the conductive path of the first arm circuit 101 and a wiring corresponding to the length of the conductive path of the second arm circuit 102 can be suppressed by the shield 20. This further improves the effect of mutual cancellation of magnetic fields between the first arm circuit 101 and the second arm circuit 102.

### Third Embodiment (Semiconductor Circuit A30)

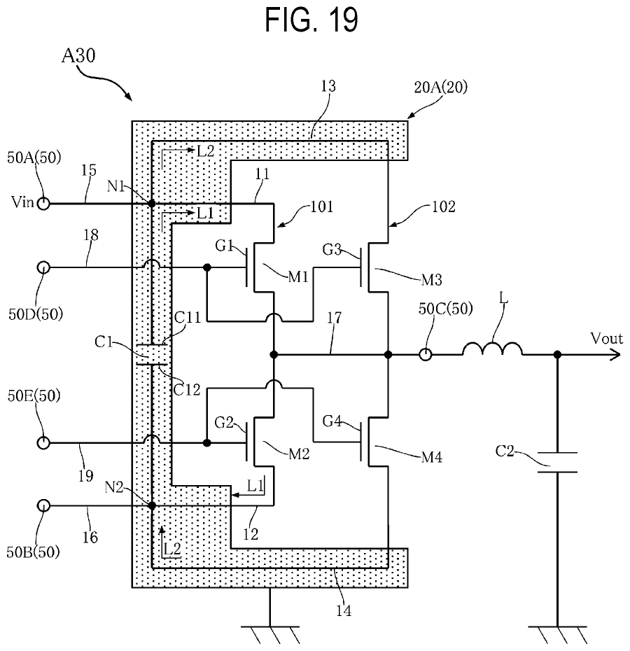

A semiconductor circuit A30 according to a third embodiment of the present disclosure will be described with reference to FIG. 19. In this figure, elements that are the same as or similar to those of the above-described semiconductor circuit A10 are denoted by the same reference numerals, and duplicate explanation thereof will be omitted.

In the semiconductor circuit A30, a configuration of the shield 20 is different from the configuration of the shield 20 in the semiconductor circuit A10.

As shown in FIG. 19, in a plan view, the shield 20 overlaps with each of the input capacitor C1, the first wiring 11 and the second wiring 12 of the first arm circuit 101, and the third wiring 13 and the fourth wiring 14 of the second arm circuit 102. Further, in a plan view, the shield 20 overlaps with each of the first node N1 and the second node N2. However, in a plan view, the third switching element M3 and the fourth switching element M4 of the second arm circuit 102 overlap with the outside of the shield 20.

As shown in FIG. 19, a length of a section of the shield 20 that overlaps with the second arm circuit 102 in a plan view and extends along the second path L2 is longer than a length of a section of the shield 20 that overlaps with the first arm circuit 101 in a plan view and extends along the first path L1.

### Third Embodiment (Semiconductor Device B30)

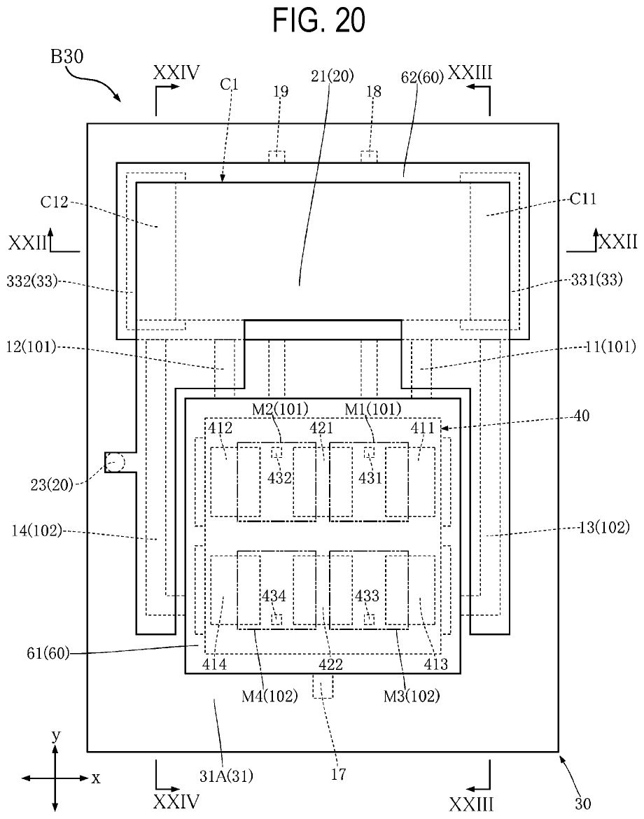

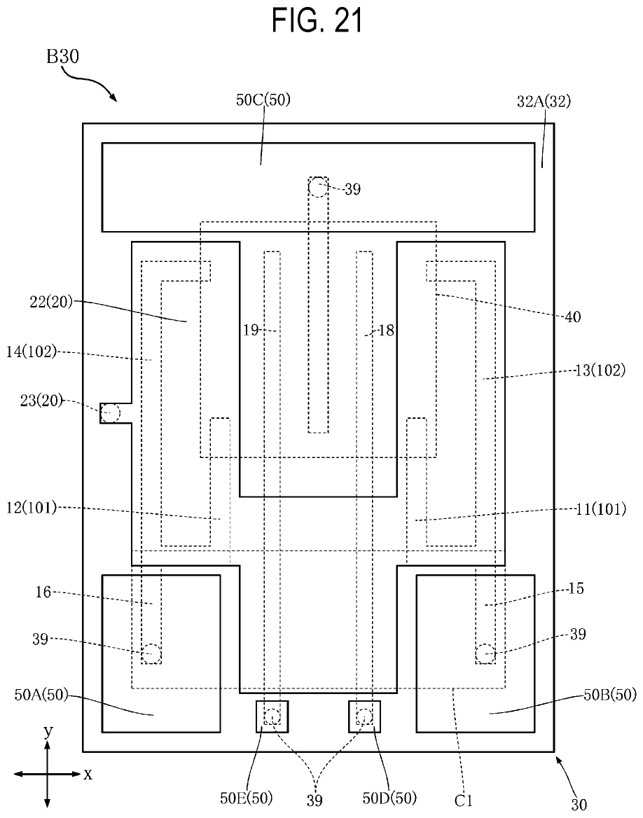

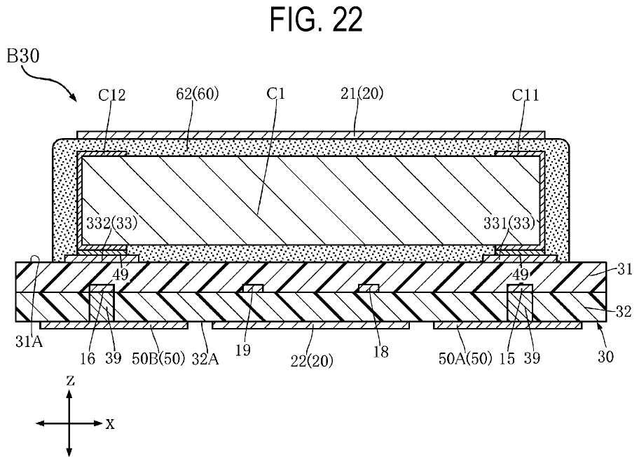

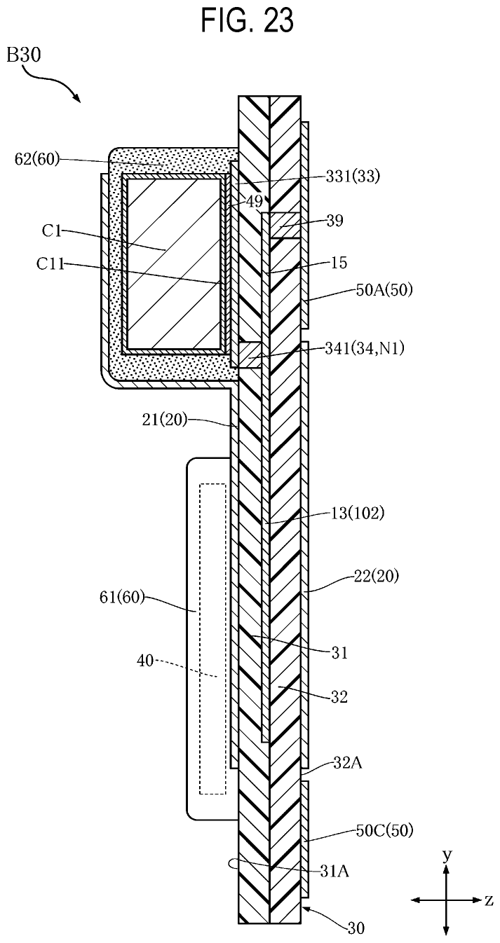

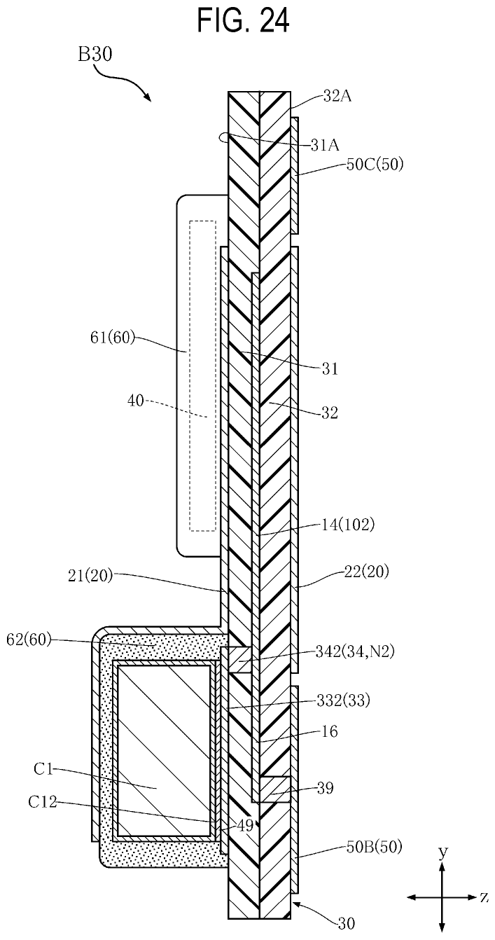

Next, a semiconductor device B30 according to the third embodiment of the present disclosure will be described with reference to FIGS. 20 to 24. In these figures, elements that are the same as or similar to those of the above-described semiconductor device B10 are denoted by the same reference numerals, and duplicate explanation thereof will be omitted.

The semiconductor device B30 includes the semiconductor circuit A30 (excluding the inductor L and the output capacitor C2) instead of the semiconductor circuit A10. Accordingly, in the semiconductor device B30, configurations of the shield 20 and the sealing resin 60 are different from the configurations of the shield 20 and the sealing resin 60 in the semiconductor device B10.

As shown in FIGS. 20 to 24, when viewed in the first direction z, each of the first shield portion 21 and the second shield portion 22 overlaps with each of the input capacitor C1, the first wiring 11, the second wiring 12, the third wiring 13, and the fourth wiring 14, which constitute the semiconductor circuit A30. Further, when viewed in the first direction z, each of the first shield portion 21 and the second shield portion 22 overlaps with each of the first gate wiring 18, the second gate wiring 19, the first contact 341, and the second contact 342, which constitute the semiconductor circuit A30. The shield 20 is separated from the semiconductor element 40 when viewed in the first direction z.

As shown in FIG. 20 and FIGS. 22 to 24, the sealing resin 60 includes only the first portion 61 and the second portion 62. Therefore, the first portion 61 and the second portion 62 are exposed to the outside. In addition, the first shield portion 21 of the first shield 20A is exposed to the outside from the main surface 31A of the first insulating layer 31. The first shield portion 21 partially covers the second portion 62 and is exposed to the outside at the second portion 62.

Next, operative effects of the semiconductor circuit A30 will be described.

The semiconductor circuit A30 includes the input capacitor C1, the first arm circuit 101 including the first switching element M1 and the second switching element M2, the second arm circuit 102 including the third switching element M3 and the fourth switching element M4, and the shield 20. The shield 20 overlaps with at least a part of the second arm circuit 102 in a plan view and is externally grounded. The length of the second path L2 of the second arm circuit 102 is longer than the length of the first path L1 of the first arm circuit 101. The length of the section of the shield 20 that overlaps with the second arm circuit 102 in a plan view and extends along the second path L2 is longer than the length of the section of the shield 20 that overlaps with the first arm circuit 101 in a plan view and extends along the first path L1. Therefore, according to this configuration, even in the semiconductor circuit A30, it is possible to reduce influence of noise caused by a configuration of a half-bridge circuit that includes a plurality of arm circuits.

In the semiconductor circuit A30, in a plan view, the shield 20 overlaps with each of the input capacitor C1, the first wiring 11 and the second wiring 12 of the first arm circuit 101, and the third wiring 13 and the fourth wiring 14 of the second arm circuit 102. By adopting this configuration, a magnetic field generated from each of a wiring corresponding to the length of the conductive path of the first arm circuit 101 and a wiring corresponding to the length of the conductive path of the second arm circuit 102 can be suppressed by the shield 20. In addition, noise generated from the input capacitor C1 can be suppressed by the shield 20. As a result, while a degree of noise generated from each of the first arm circuit 101 and the second arm circuit 102 approaches an equivalent state, influence of noise from the input capacitor C1 on each of the first arm circuit 101 and the second arm circuit 102 can be suppressed. This configuration is beneficial to the semiconductor circuit A30 in which the length of the conductive path of the first arm circuit 101 and the length of the conductive path of the second arm circuit 102 are each relatively long and the capacitance of the input capacitor C1 is relatively large.

The present disclosure is not limited to the above-described embodiments. The specific configuration of each part of the present disclosure can be modified in design in various ways.

The present disclosure includes embodiments described in the following supplementary notes.

### [Supplementary Note 1]

A semiconductor circuit including:
an input capacitor having a first electrode and a second electrode;
a first arm circuit including a first switching element and a second switching element that are connected in series with each other, wherein the first switching element is electrically connected to the first electrode, and the second switching element is electrically connected to the second electrode;
a second arm circuit including a third switching element and a fourth switching element that are connected in series with each other, wherein the third switching element is electrically connected to the first electrode, and the fourth switching element is electrically connected to the second electrode; and
a shield that overlaps with at least a part of the second arm circuit in a plan view and is externally grounded,
wherein the first arm circuit has a first path from a first node having a same potential as the first electrode to a second node having a same potential as the second electrode,
wherein the second arm circuit has a second path from the first node to the second node,
wherein a length of the second path is longer than a length of the first path, and
wherein a length of a section of the shield that overlaps with the second arm circuit in a plan view and extends along the second path is longer than a length of a section of the shield that overlaps with the first arm circuit in a plan view and extends along the first path.

### [Supplementary Note 2]

The semiconductor circuit of Supplementary Note 1, wherein the shield overlaps with an entirety of the second arm circuit in a plan view.

### [Supplementary Note 3]

The semiconductor circuit of Supplementary Note 1, wherein the first arm circuit further includes a first wiring that electrically connects the first node and the first switching element, and a second wiring that electrically connects the second node and the second switching element,
wherein the second arm circuit further includes a third wiring that electrically connects the first node and the third switching element, and a fourth wiring that electrically connects the second node and the fourth switching element, and
wherein the shield overlaps with at least the third wiring and the fourth wiring in a plan view.

### [Supplementary Note 4]

The semiconductor circuit of Supplementary Note 3, wherein the shield includes a first shield and a second shield that are separated from each other,
wherein the first shield overlaps with the third wiring in a plan view, and
wherein the second shield overlaps with the fourth wiring in a plan view.

### [Supplementary Note 5]

The semiconductor circuit of Supplementary Note 4, wherein the first shield overlaps with the first wiring in a plan view, and
wherein the second shield overlaps with the second wiring in a plan view.

### [Supplementary Note 6]

The semiconductor circuit of Supplementary Note 3, wherein the shield overlaps with each of the input capacitor, the first wiring, the second wiring, the third wiring, and the fourth wiring in a plan view.

### [Supplementary Note 7]

The semiconductor circuit of any one of Supplementary Notes 1 to 6, further including an inductor electrically connected to the first switching element, the second switching element, the third switching element, and the fourth switching element,
wherein the inductor is located outside the shield in a plan view.

### [Supplementary Note 8]

The semiconductor circuit of Supplementary Note 7, further including an output capacitor electrically connected to the inductor,
wherein the output capacitor is located outside the shield in a plan view.

### [Supplementary Note 9]

A semiconductor device including:
a semiconductor circuit of Supplementary Note 1; and
a base material on which the semiconductor circuit is mounted.

### [Supplementary Note 10]

The semiconductor device of Supplementary Note 9, wherein a part of each of the first arm circuit and the second arm circuit is accommodated in the base material, and wherein the input capacitor is conductively bonded to the base material.

### [Supplementary Note 11]

The semiconductor device of Supplementary Note 10, further including a semiconductor element including the first switching element, the second switching element, the third switching element, and the fourth switching element,
wherein the semiconductor element is conductively bonded to the base material.

### [Supplementary Note 12]

The semiconductor device of Supplementary Note 11, further including a sealing resin that covers the semiconductor element.

### [Supplementary Note 13]

The semiconductor device of Supplementary Note 12, wherein the base material has a main surface facing the semiconductor element in a first direction, and a back surface facing opposite to the main surface in the first direction, and
wherein the shield is exposed to the outside from the back surface.

### [Supplementary Note 14]

The semiconductor device of Supplementary Note 13, wherein the shield is exposed to the outside from the main surface.

### [Supplementary Note 15]

The semiconductor device of Supplementary Note 13, wherein a part of the shield is accommodated in the sealing resin.

### [Supplementary Note 16]

The semiconductor device of Supplementary Note 14 or 15, wherein the sealing resin covers the input capacitor.

### [Supplementary Note 17]

The semiconductor device of any one of Supplementary Notes 13 to 15, further including a plurality of terminals exposed to the outside from the back surface,
wherein each of the plurality of terminals is electrically connected to at least one of the input capacitor, the first arm circuit, or the second arm circuit.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor circuit comprising:
an input capacitor having a first electrode and a second electrode;
a first arm circuit including a first switching element and a second switching element that are connected in series with each other, wherein the first switching element is electrically connected to the first electrode, and the second switching element is electrically connected to the second electrode;
a second arm circuit including a third switching element and a fourth switching element that are connected in series with each other, wherein the third switching element is electrically connected to the first electrode, and the fourth switching element is electrically connected to the second electrode; and
a shield that overlaps with at least a part of the second arm circuit in a plan view and is externally grounded,
wherein the first arm circuit has a first path from a first node having a same potential as the first electrode to a second node having a same potential as the second electrode,
wherein the second arm circuit has a second path from the first node to the second node,
wherein a length of the second path is longer than a length of the first path, and
wherein a length of a section of the shield that overlaps with the second arm circuit in a plan view and extends along the second path is longer than a length of a section of the shield that overlaps with the first arm circuit in a plan view and extends along the first path.

2. The semiconductor circuit of claim 1, wherein the shield overlaps with an entirety of the second arm circuit in a plan view.

3. The semiconductor circuit of claim 1, wherein the first arm circuit further includes a first wiring that electrically connects the first node and the first switching element, and a second wiring that electrically connects the second node and the second switching element,
wherein the second arm circuit further includes a third wiring that electrically connects the first node and the third switching element, and a fourth wiring that electrically connects the second node and the fourth switching element, and
wherein the shield overlaps with at least the third wiring and the fourth wiring in a plan view.

4. The semiconductor circuit of claim 3, wherein the shield includes a first shield and a second shield that are separated from each other,
wherein the first shield overlaps with the third wiring in a plan view, and
wherein the second shield overlaps with the fourth wiring in a plan view.

5. The semiconductor circuit of claim 4, wherein the first shield overlaps with the first wiring in a plan view, and
wherein the second shield overlaps with the second wiring in a plan view.

6. The semiconductor circuit of claim 3, wherein the shield overlaps with each of the input capacitor, the first wiring, the second wiring, the third wiring, and the fourth wiring in a plan view.

7. The semiconductor circuit of claim 1, further comprising an inductor electrically connected to the first switching element, the second switching element, the third switching element, and the fourth switching element,
wherein the inductor is located outside the shield in a plan view.

8. The semiconductor circuit of claim 7, further comprising an output capacitor electrically connected to the inductor,
wherein the output capacitor is located outside the shield in a plan view.

9. A semiconductor device comprising:
a semiconductor circuit of claim 1; and
a base material on which the semiconductor circuit is mounted.

10. The semiconductor device of claim 9, wherein a part of each of the first arm circuit and the second arm circuit is accommodated in the base material, and
wherein the input capacitor is conductively bonded to the base material.

11. The semiconductor device of claim 10, further comprising a semiconductor element including the first switching element, the second switching element, the third switching element, and the fourth switching element,
wherein the semiconductor element is conductively bonded to the base material.

12. The semiconductor device of claim 11, further comprising a sealing resin that covers at least the semiconductor element.

13. The semiconductor device of claim 12, wherein the base material has a main surface facing the semiconductor element in a first direction, and a back surface facing opposite to the main surface in the first direction, and
wherein the shield is exposed to the outside from the back surface.

14. The semiconductor device of claim 13, wherein the shield is exposed to the outside from the main surface.

15. The semiconductor device of claim 13, wherein a part of the shield is accommodated in the sealing resin.

16. The semiconductor device of claim 14, wherein the sealing resin covers the input capacitor.

17. The semiconductor device of claim 13, further comprising a plurality of terminals exposed to the outside from the back surface,
wherein each of the plurality of terminals is electrically connected to at least one of the input capacitor, the first arm circuit, or the second arm circuit.
